(19) United States
(12) Patent Application Publication
(10) Pub. No.: US 2025/0120189 A1
(43) Pub. Date: Apr. 10, 2025

(54) Multi-Junction Broadband Photodetector

(71) Applicant: Marvell Asia Pte Ltd, Singapore (SG)

(72) Inventors: Hamed Pishvaibazargani, Stittsville (CA); Jie Lin, Santa Clara, CA (US); Masaki Kato, Palo Alto, CA (US)

(21) Appl. No.: 18/909,993

(22) Filed: Oct. 9, 2024

Related U.S. Application Data
(60) Provisional application No. 63/543,276, filed on Oct. 9, 2023.

(51) Int. Cl. H01L 31/109; H01L 31/0224; H01L 31/18

(52) U.S. Cl. CPC H10F 30/222; H10F 71/121; H10F 77/206

(57) ABSTRACT

An optical communication system includes an optical waveguide and a photodetector (PD). The optical waveguide is arranged to receive and guide an optical signal. The PD is configured to receive the optical signal from the optical waveguide and to convert the optical signal into an electrical signal. The PD includes a stack of layers including at least (i) first layers including two or more semiconductor layers forming a reverse-biased semiconductor junction configured to produce the electrical signal in response to the optical signal impinging thereon, and (ii) second layers forming a capacitance component that in is connected with series the reverse-biased semiconductor junction. The PD further includes a first electrode and a second electrode, configured to (i) apply one or more voltages that reverse-bias the reverse-biased semiconductor junction and (ii) output the electrical signal.

### CROSS-REFERENCE TO RELATED APPLICATIONS

This application claims the benefit of U.S. Provisional Patent Application 63/543,276, filed Oct. 9, 2023, whose disclosure is incorporated herein by reference.

### FIELD OF THE DISCLOSURE

The present disclosure relates generally to optical communication, and particularly to photodetector design.

### BACKGROUND

Photodetectors (PDs) are fundamental building blocks in optical communication devices and other opto-electronic systems. Some PDs are fabricated using III-V semiconductors such as gallium arsenide (GaAs). Other PDs are realized using Silicon-On-Insulator (SOI) technologies.

A general review of Silicon-Based PDs is provided by Gupta and Kedia, in “A Review on Silicon-Based Photodetectors,” International Journal of Innovative Research in Science, Engineering and Technology, Volume 5, Issue 2, February 2016.

Some SOI-based PDs use germanium as the light absorbing layer. Si—Ge PDs are described, for example, by Ito and Ishikawa, in “Waveguide-Integrated Vertical pin Photodiodes of Ge Fabricated on p+ and n+ Si-on-Insulator Layers,” Extended Abstracts of the 2016 International Conference on Solid State Devices and Materials, Tsukuba, Japan, 2016; and by Hu et al., in “High-speed and high-power germanium photodetector with a lateral silicon nitride waveguide,” Photonics Research, Volume 9, No. 5, May 2021.

The description above is presented as a general overview of related art in this field and should not be construed as an admission that any of the information it contains constitutes prior art against the present patent application.

### SUMMARY

An embodiment that is described herein provides an optical communication system including an optical waveguide and a photodetector (PD). The optical waveguide is arranged to receive and guide an optical signal. The PD is configured to receive the optical signal from the optical waveguide and to convert the optical signal into an electrical signal. The PD includes a stack of layers including at least (i) first layers including two or more semiconductor layers forming a reverse-biased semiconductor junction configured to produce the electrical signal in response to the optical signal impinging thereon, and (ii) second layers forming a capacitance component that is connected in series with the reverse-biased semiconductor junction. The PD further includes a first electrode and a second electrode, configured to (i) apply one or more voltages that reverse-bias the reverse-biased semiconductor junction and (ii) output the electrical signal.

In some embodiments, the first layers include at least a silicon layer and a germanium layer. In some embodiments, the stack of layers is compatible for fabrication with a Complementary Metal-Oxide-Semiconductor (CMOS) fabrication process. In some embodiments, at least one of the layers in the stack belongs both to the first layers and to the second layers.

In some embodiments, the second layers form a forward-biased semiconductor junction, and the one or more voltages are set to bias both the forward-biased semiconductor junction and the reverse-biased semiconductor junction. In an example embodiment, the optical communication system further includes a third electrode, which is connected between the forward-biased semiconductor junction and the reverse-biased semiconductor junction and is configured to apply an additional voltage for applying a further bias to the forward-biased semiconductor junction and to the reverse-biased semiconductor junction.

In an alternative embodiment, the second layers include at least one dielectric layer and at least one metal layer that form a capacitor.

In an embodiment, the stack of layers includes: an N-doped silicon n layer; a P-doped silicon layer disposed on or in the N-doped silicon layer; an intrinsic (I) germanium layer disposed on the P-doped silicon layer; and an additional N-doped silicon layer disposed on the germanium layer. In another embodiment, the stack of layers includes: a P-doped silicon layer; an N-doped silicon layer disposed on or in the P-doped silicon layer; an intrinsic (I) germanium layer disposed on the N-doped silicon layer; and an additional P-doped silicon layer disposed on the germanium layer.

There is additionally provided, in accordance with an embodiment that is described herein, a method of manufacturing an optical communication system. The method includes disposing, on a substrate, a photodetector (PD) for converting an optical signal into an electrical signal. Disposing the PD includes disposing a stack of layers, including at least (i) first layers including two or more semiconductor layers forming a reverse-biased semiconductor junction configured to produce the electrical signal in response to the optical signal impinging thereon, and (ii) second layers forming a capacitance component that is connected in series with the reverse-biased semiconductor junction. Disposing the PD further includes disposing a first electrode and a second electrode, configured to (i) apply one or more voltages that reverse-bias the reverse-biased semiconductor junction and (ii) output the electrical signal. An optical waveguide is disposed on a substrate, for receiving and guiding the optical signal to the PD.

The present disclosure will be more fully understood from the following detailed description of the embodiments thereof, taken together with the drawings in which:

### BRIEF DESCRIPTION OF THE DRAWINGS

FIG. 1 is a block diagram that schematically illustrates an optical communication system that uses multi-junction PDs, in accordance with an embodiment that is described herein;

FIG. 2 is a three-dimensional view of a multi-junction PD used in the system of FIG. 1, in accordance with an embodiment that is described herein;

FIGS. 3A, 3B, 4A, 4B, 5A, 5B, 6A and 6B are cross-sectional views of multi-junction PDs, in accordance with alternative embodiments that are described herein; and

FIGS. 7A, 7B, 8A, 8B, 9A and 9B are graphs illustrating simulated performance of multi-junction PDs, in accordance with embodiments that are described herein, in comparison with conventional PIN PDs.

### DETAILED DESCRIPTION OF EMBODIMENTS

A photodetector (PD) is an Electro-Optical (EO) device that converts light into electrical current. In an optical communication system, a PD typically converts a modulated optical signal into a modulated electrical signal.

A PD may be implemented, for example, using a reverse-biased Positive-Intrinsic-Negative (PIN) or Negative-Intrinsic-Positive (NIP) semiconductor junction (i.e., a PIN or NIP diode). The Intrinsic (I) layer of the junction is an optically active layer that absorbs photons and causes the instantaneous current via the junction to follow the instantaneous optical intensity.

The reverse-biased junction may be implemented using III-V materials such as GaAs, or using Silicon-On-Insulator (SOI) technology in which the Intrinsic layer is made of germanium. Si—Ge PDs are often preferred to mass production applications, since they are compatible with Complementary Metal-Oxide-Semiconductor (CMOS) fabrication processes. The present disclosure refers mainly to Si—Ge PDs, but the disclosed techniques are applicable to PDs implemented in any other suitable semiconductor materials.

Two major figures-of-merit in PD design are bandwidth and responsivity. Responsivity is defined as the electrical current generated by the PD per unit of optical input power.

The bandwidth of a PD depends on (i) the charge-carrier transit time in Ge, and (ii) the Resistance-Capacitance (RC) time constant of the junction. This dependence can be written as:

$${f}_{3 db} = \frac{1}{\sqrt{{f}_{R C}^{- 2} + {f}_{tr}^{- 2}}}$$

wherein f_{3db} denotes the bandwidth of the PD, f_{RC} denotes the bandwidth limit due to the junction RC, and fₜᵣ denotes the bandwidth limit due to charge-carrier transit time; f_{RC} can be written as f_{RC}=1/(2πRC), and fₜᵣ can be written as fₜᵣ=(0.45·6e6)/(Ge thickness in cm).

As seen, the transit-time limited bandwidth fₜᵣ is dictated by the thickness of the Ge layer, which is typically fixed based on the fab process. A thinner Ge layer would improve the transit-time limited bandwidth fₜᵣ, but will have an adverse effect on the PD responsivity.

Another important trade-off has to do with the length of the PD. A longer junction (up to a limit at which all input light is absorbed) typically exhibits better responsivity, but on the other hand has a larger capacitance that reduces the PD bandwidth.

Embodiments that are described herein provide improved optical communication systems, and improved PD designs for use in such systems, which break the traditional trade-off between responsivity and bandwidth. The disclosed PDs exhibit large bandwidth without degrading responsivity.

In some embodiments, a disclosed PD comprises a stack of layers disposed on a substrate. The stack includes at least:
“First layers”—A reverse-biased semiconductor junction, e.g., a PIN or NIP Si—Ge junction, which produces an electrical signal in response to an optical signal impinging thereon.
“Second layers” (which may have at least one layer in common with the “first layers”)—A capacitance component, e.g., a forward-biased PN or NP silicon junction, which is connected in series with the reverse-biased semiconductor junction.

The capacitance component in the stack forms a series capacitance that, in combination with the capacitance of the reverse-biased junction, yields a low total capacitance and therefore large bandwidth.

When realized using a forward-biased semiconductor junction, the voltage drop across the capacitance component is small, e.g., 0.7V for silicon. In conventional PD design, the only way to reduce the PD capacitance is to shorten the PD, i.e., reduce the PD length. This shortening, however, increases the PD's RC-limited bandwidth. Shortening the PD length increases the resistance of the PD, which is highly undesirable. When using a forward-biased semiconductor junction in the disclosed embodiments, the total capacitance of the PD is reduced without the need to shorten the device. Therefore, the RC-limited bandwidth of the PD can be increased without any increase in the PD resistance. Low resistance is highly desirable, for example, in a communication system in which the PD is followed by a high-gain Trans-Impedance Amplifier (TIA). In such a configuration, a PD having low resistance is crucial for ensuring low noise levels.

Moreover, the incorporation of the forward-biased junction in the stack increases the gain of the PD.

In summary, the disclosed techniques provide PDs that exhibit large bandwidth, high responsivity, high gain and small resistance. The disclosed PDs are fully compatible with CMOS fabrication processes, and are therefore simple to integrate with other optical communication system elements. Multiple implementations of the disclosed PDs are described herein. Simulated performance is also presented and compared with conventional PD performance.

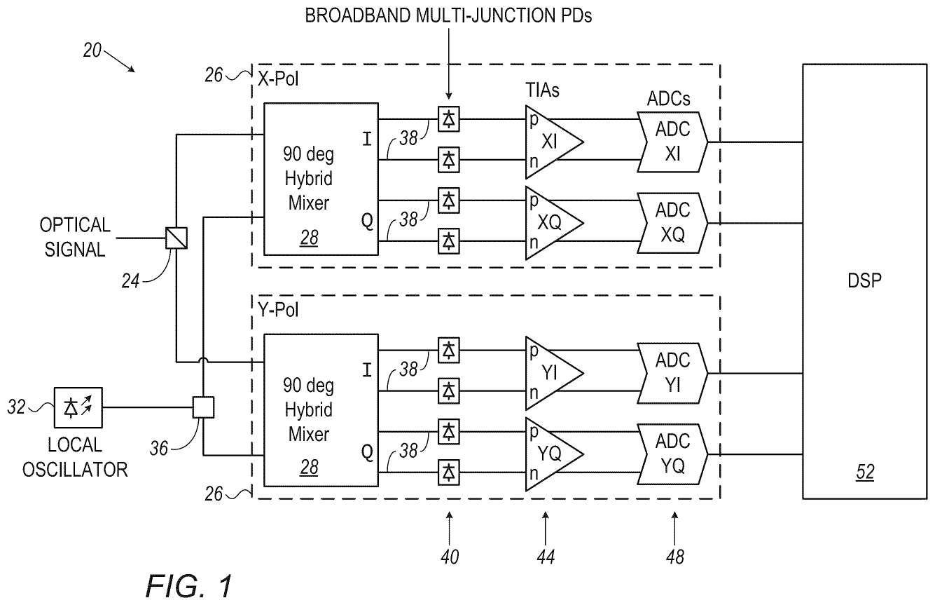

FIG. 1 is a block diagram that schematically illustrates an optical communication system 20 that uses multi-junction PDs, in accordance with an embodiment that is described herein. In the present example, system 20 receives a dual-polarization optical signal, e.g., from an optical fiber. System 20 mixes the optical signal with a Local Oscillator (LO) signal and separates the resulting optical signal into four differential signal components—An In-phase (I) component and a Quadrature (Q) component for each polarization. The system then detects the four differential signal components using eight multi-junction PDs. The structure and operation of the multi-junction PDs are explained in detail further below. The resulting eight electrical signals are amplified, digitized and output for further processing.

In the example of FIG. 1, the input optical signal is split into an X-polarized (“X-pol”) signal and a Y-polarized (“Y-pol”) signal by a Polarizing Beam Splitter (PBS) 24. The X-pol and Y-pol signals are provided to a pair of receiver circuits 26 denoted “X-pol” and “Y-pol”, respectively. Receivers 26 are also provided with an optical LO signal, which is produced by a laser diode 32, via a beam Splitter (BS) 36.

Each receiver 26 comprises a 90-degree hybrid mixer 28 that performs quadrature mixing between the optical signal (X-pol or Y-pol) and the LO signal. Mixer signal components 28 outputs two differential corresponding to the I and Q components of the optical signal (X-pol or Y-pol). Each differential signal component is output via a pair of optical waveguides 38. Two pairs of multi-junction PDs 40 receive the two differential signal components from waveguides 38, and convert them into two differential electrical signals. A pair of differential Trans-Impedance Amplifiers (TIAs) 44 amplify the two differential electrical signals. A pair of Analog-to-Digital Converters (ADCs) 48 digitize the two differential electrical signals. The resulting digitized signals are provided to a Digital Signal Processor (DSP) 52 for further processing, e.g., filtering, demodulation and the like.

The configuration of optical communication system 20, as shown in FIG. 1, is an example configuration that is depicted solely for the sake of clarity. In alternative embodiments, one or more multi-junction PDs 40 may be applied in any other suitable optical communication system. Non-limiting examples of optical systems, communication or otherwise, which may comprise PDs 40 include coherent and non-coherent optical communication systems, radiometry systems, photonics systems, microscopes, television and other remote-control devices, in laser printing systems, displays, optical data recording systems, optical power and flux measurement systems, vision scanners, security systems and many others.

The various elements of system 20 may be implemented using dedicated hardware, such as using discrete or integrated optical components, in a System-on-Chip (SoC) that integrates optical and electronic components, or using any other suitable technology.

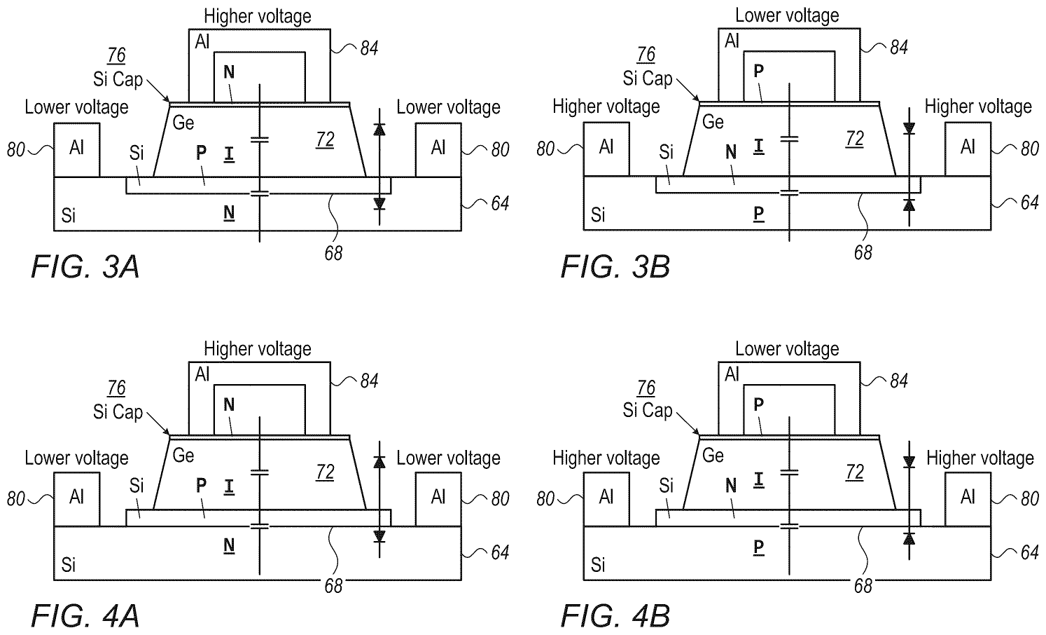

FIGS. 3A, 3B, 4A, 4B, 5A, 5B, 6A and 6B are cross-sectional views of multi-junction PDs, in accordance with alternative embodiments that are described herein. These example PDs can be used, for example, as PDs 40 in system 20 of FIG. 1, or in any other suitable system or device.

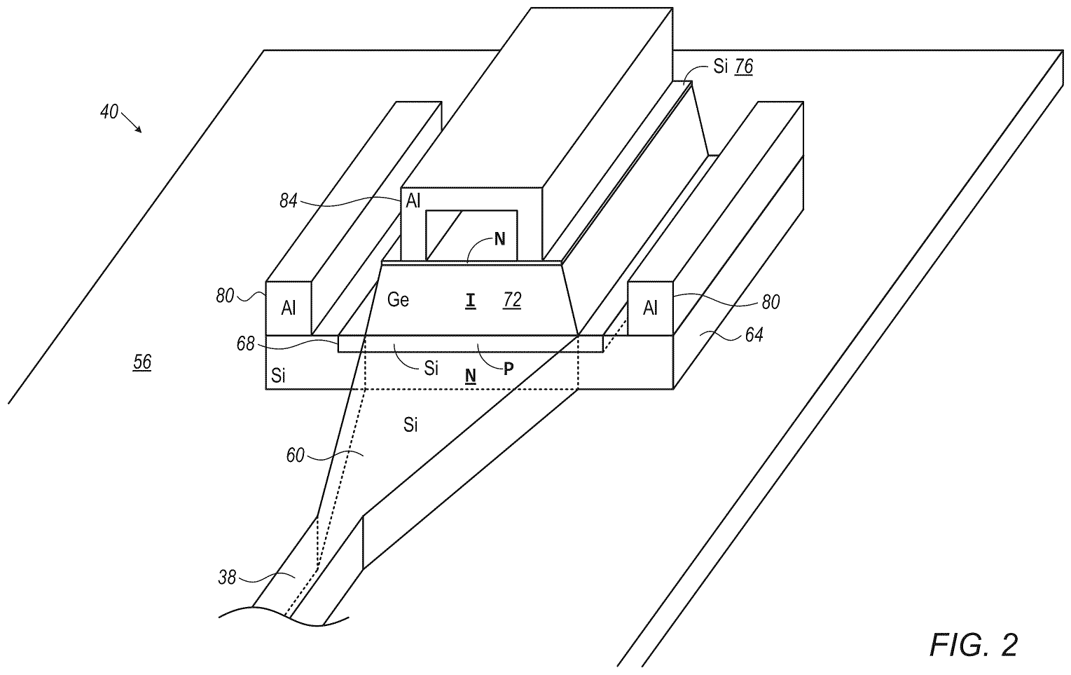

FIG. 2 is a three-dimensional view of a multi-junction PD 40, in accordance with an embodiment that is described herein. PD 40 is disposed on a substrate 56. Substrate 56 is typically made of silicon. In an embodiment, substrate 56 comprises a silicon base, on which a 2-3 μm layer of buried oxide is disposed, with a 220 nm layer of silicon disposed on the buried oxide. PD 40 comprises a stack of multiple semiconductor layers that are disposed on one another.

In the embodiment of FIG. 2, the stack comprises the following layers, from bottom to top (i.e., from the layer that is directly attached to substrate 56 to the layer that is furthest away from substrate 56):
An N-doped silicon (Si) layer 64.
A P-doped Si layer 68. In the present example, layer 68 is implemented as a P-doped region within layer 64. An alternative implementation is described below.
An Intrinsic (I) germanium (Ge) layer 72.
A P-doped Si cap layer 76.

In addition, PD 40 comprises two aluminum (Al) electrodesAn electrode 80 connected to layer 80, and an electrode 84 connected to layer 84.

Light (e.g., a modulated optical signal) is coupled to PD 40 from an optical waveguide 38 laid on substrate 56. Waveguide 38 has a tapered section 60 that couples the light to layer 64. In an example implementation, PD 40 has the following dimensions:
Overall width: 4 μm-to-9 μm.
Overall length: 5 μm-to-30 μm.
Layer thicknesses: Layer 64—220 nm; Layer 68—220 nm; Layer 72—100 nm-to-500 nm; Layer 76—50 nm-to-100 nm.

Alternatively, any other suitable dimensions can be used.

FIG. 3A is a cross-sectional view of PD 40 of FIG. 2, focusing on the stack of layers 64, 68, 72 and 76, and on electrical biasing using electrodes 80 and 84, in accordance with an embodiment that is described herein.

In an embodiment, electrode 80 is connected to a certain voltage, e.g., 0V, and electrode 84 is connected to a higher voltage, e.g., 2V.

With this biasing, layers 76, 72 and 68 form a reverse-biased NIP junction; and layers 64 and 68 form a forward-biased PN junction. The two junctions are illustrated using diodes in the figure. As seen, layer 68 is common to both junctions.

The reverse-biased NIP junction (layers 76, 72 and 68) is configured to perform the actual photodetection. The electrical current generated by the photodetection is output via electrodes 80 and 84.

The forward-biased junction (layers 64 and 68) serves as a capacitance component that is connected in series with the reverse-biased NIP junction. The capacitances of the two junctions are illustrated as capacitors in the figure.

Due to the series connection of capacitances, the total capacitance of PD 40 is smaller than the capacitance of the reverse-biased NIP junction alone. In various implementations, the reduction in capacitance is in the range of 58-30%. Therefore, the bandwidth of PD 40 is larger than the bandwidth of the reverse-biased NIP junction alone. At the same time, the responsivity of the reverse-biased NIP junction alone is not compromised.

Another important property of PD 40 stems from the fact that the voltage drop across the forward-biased junction (layers 64 and 68) is small, in the present example 0.7 volts. As explained above, this enables reducing the capacitance and therefore increasing the bandwidth of the PD, without undesirably increasing its resistance. A small resistance is important for reducing noise levels (especially in systems such as system 20, in which the output of PD 40 is amplified by a high-gain TIA 44).

FIG. 3B is a cross-sectional view of a multi-junction PD, in accordance with an alternative embodiment that is described herein. The PD of FIG. 3B is similar in structure to the PD of FIG. 3A, but has opposite doping polarities. In the PD of FIG. 3B, Si layer 64 is P-doped, Si layer (region) 68 is N-doped, and Si cap layer 76 is P-doped. In other words, the stack of layers in FIG. 3A is a “NIPN” stack, whereas the stack of layers in FIG. 3B is a “PINP” stack.

In the configuration of FIG. 3B, the voltage applied to electrode 80 (e.g., 2V) is higher than the voltage applied to electrode 84 (e.g., 0V). With this biasing, layers 76, 72 and 68 form a reverse-biased PIN junction; and layers 64 and 68 form a forward-biased NP junction. The performance of this PD is essentially equivalent to the PD of FIG. 3A.

FIG. 4A is a cross-sectional view of a multi-junction PD, in accordance with another embodiment that is described herein. The PD of FIG. 4A is similar in structure to the PD of FIG. 3A, with the exception that Si layer 68 is a separate layer disposed on top of Si layer 64, rather than an oppositely doped region within layer 64. In this configuration, layer 68 is typically selectively grown on top of layer 64. Fabricating layer 68 as a separate layer may be simpler, since doping of layer 68 starts from neutral silicon, not from an oppositely doped layer as in FIG. 3A.

FIG. 4B is a cross-sectional view of a multi-junction PD, in accordance with an alternative embodiment that is described herein. The PD of FIG. 4B is similar in structure to the PD of FIG. 4A, but has opposite doping polarities.

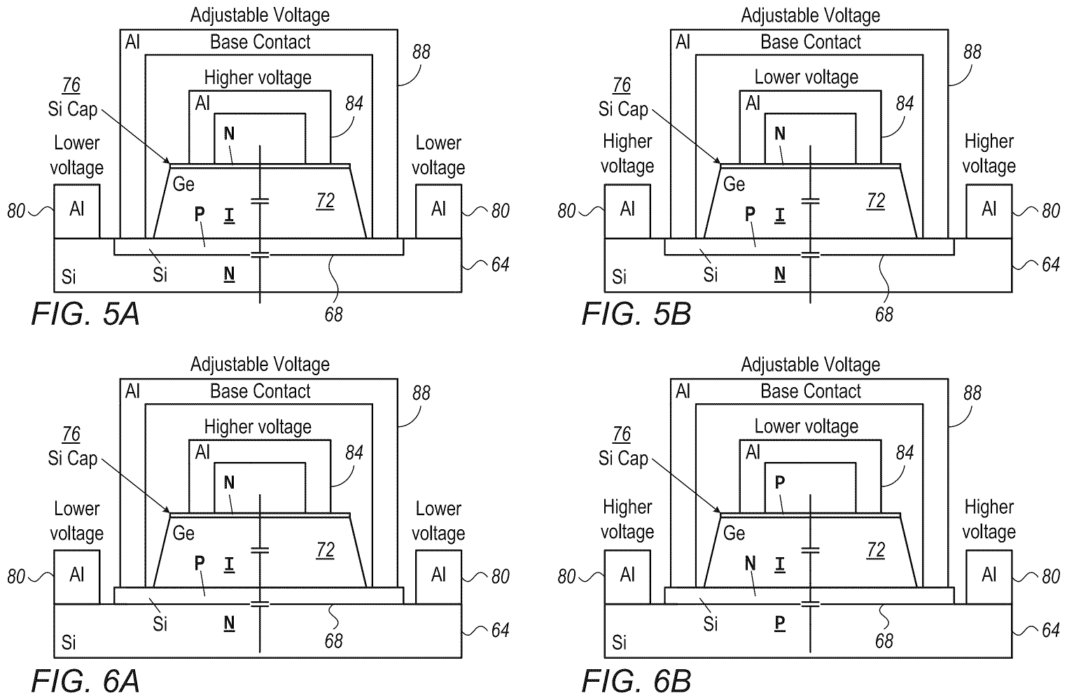

FIG. 5A is a cross-sectional view of a multi-junction PD, in accordance with yet another embodiment that is described herein. The PD of FIG. 5A is similar in structure to the PD of FIG. 3A, with the exception that an additional aluminum electrode 88 (labeled “base contact”) is added. Electrode 88 is configured to apply an adjustable voltage to Si layer 68. This adjustable voltage can be used to better control the voltage drops across the reverse-biased junction (layers 76, 72 and 68) and the forward-biased junction (layers 64 and 68). Adjusting the base voltage applied to electrode 88 enables adjustment of the gain and bandwidth of the PD.

FIG. 5B is a cross-sectional view of a multi-junction PD, in accordance with an alternative embodiment that is described herein. The PD of FIG. 5B is similar in structure to the PD of FIG. 5A, but has opposite doping polarities.

FIG. 6A is a cross-sectional view of a multi-junction PD, in accordance with another embodiment that is described herein. The PD of FIG. 6A is similar in structure to the PD of FIG. 5A, with the exception that Si layer 68 is a separate layer that is selectively grown on top of Si layer 64.

FIG. 6B is a cross-sectional view of a multi-junction PD, in accordance with an alternative embodiment that is described herein. The PD of FIG. 6B is similar in structure to the PD of FIG. 6A, but has opposite doping polarities.

The PD configurations shown in FIGS. 3A, 3B, 4A, 4B, 5A, 5B, 6A and 6B are example configurations that are depicted solely for the sake of conceptual clarity. In alternative embodiments, any other suitable configuration can be used.

For example, in alternative embodiments, the forward-biased junction of the PD can be replaced by any other suitable structure of one or more layers that form a capacitance component. For example, a PD may comprise (instead of a forward-biased junction) at least one dielectric layer and at least one metal layer that form a capacitor. Such layers may be disposed on top of the reverse-biased junction.

As another example, the PD configurations described are vertically stacked and use vertical doping. In alternative embodiments, PDs according to the disclosed techniques can also be fabricated using lateral doping, resulting in a stack of layers that is orthogonal to substrate 56.

In various embodiments, the various PDs shown in FIGS. 3A, 3B, 4A, 4B, 5A, 5B, 6A and 6B can be fabricated in various processes. Typically, the various layers in the stack of the PD are grown epitaxially on top of one another. The fabrication process is typically compatible with CMOS processes, and may be carried out in a CMOS fab.

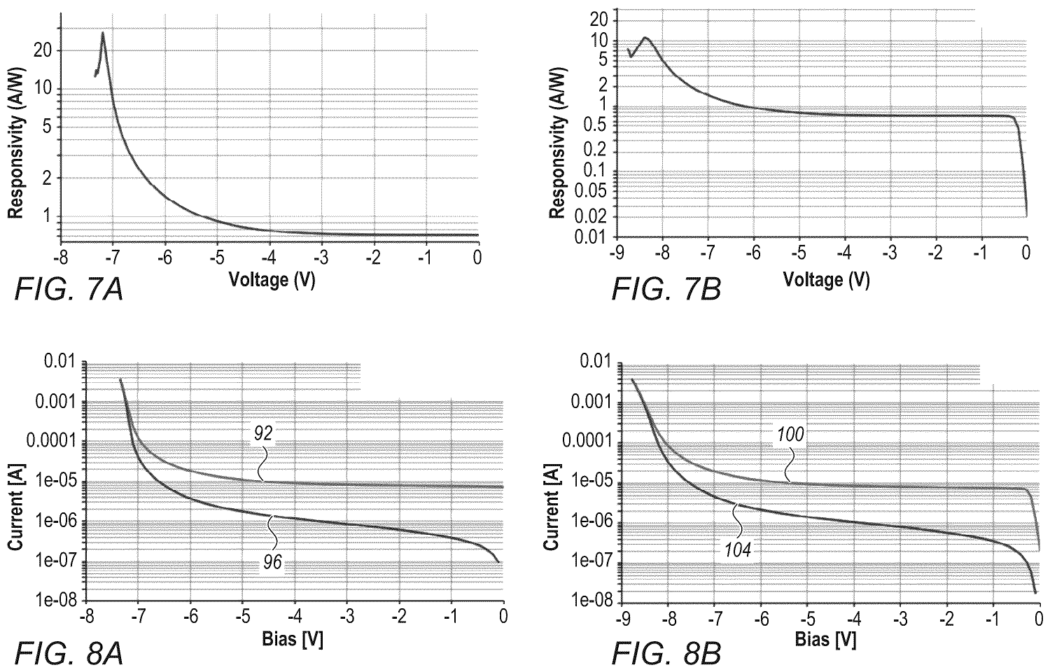

FIGS. 7A, 7B, 8A, 8B, 9A and 9B are graphs illustrating simulated performance of multi-junction PDs, in accordance with embodiments that are described herein, in comparison with conventional PIN PDs. The vertical axes in the figures show performance measures such as responsivity, dark current, photocurrent and gain. The horizontal axis in all the figures denotes the bias voltage across the reverse-biased junction (layers 76, 72 and 68), i.e., the bias between electrodes 80 and 84. The forward-biased junction takes only ˜0.7V out of the total bias.

FIGS. 7A and 7B compare the responsivity of a disclosed multi-junction PD (FIG. 7B) to a comparable conventional PD (FIG. 7A). FIGS. 8A and 8B compare the dark current and photocurrent of a disclosed multi-junction PD (FIG. 8B) to a comparable conventional PD (FIG. 8A). In FIG. 8A, plots 92 and 96 illustrate the photocurrent and dark current, respectively, for a conventional PD. In FIG. 8B, plots 100 and 104 illustrate the photocurrent and dark current, respectively, for a disclosed multi-junction PD.

As seen, the responsivity, dark current and photocurrent are similar within the normal operation range (voltage bias between −1 and −6 volts). The capacitance of the disclosed multi-junction PD, however, is smaller by ˜18% in the present example than the capacitance of the conventional PD. This difference in capacitance translates to an 18% increase in bandwidth.

Since the forward-biased junction deducts 0.7 volts from the overall bias, the “knee” point in the response of the PD occurs at a slightly higher voltage in the multi-junction PD.

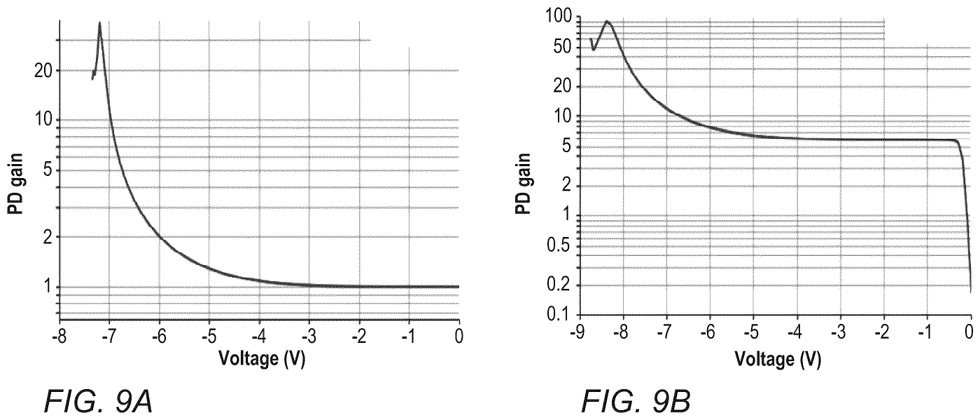

FIGS. 9A and 9B compare the gain of a disclosed multi-junction PD (FIG. 7B) to a comparable conventional PD (FIG. 7A). The gain is defined as:

$$gain = \frac{\vert P h o t o c u r r e n t ( V ) - D a r k c u r r e n t ( V ) \vert}{\vert P h o t o c u r r e n t ( 0 ) - D a r k c u r r e n t ( 0 ) \vert}$$

As seen, the disclosed multi-junction PD (FIG. 9B) exhibits a gain of approximately ×6, whereas the conventional PD (FIG. 9A) gain exhibits a of approximately unity, i.e., no gain. This increase in gain is in addition to the increase in bandwidth, as explained above.

Although the embodiments described herein mainly address PDs in optical communication systems, the methods and systems described herein can also be used in other applications, such as in lidar systems, avalanche PDs, and others.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An optical communication system, comprising:
an optical waveguide arranged to receive and guide an optical signal; and
a photodetector (PD) configured to receive the optical signal from the optical waveguide and to convert the optical signal into an electrical signal, the PD comprising:
a stack of layers, comprising at least:
first layers including two or more semiconductor layers forming a reverse-biased semiconductor junction configured to produce the electrical signal in response to the optical signal impinging thereon; and
second layers forming a capacitance component that is connected in series with the reverse-biased semiconductor junction; and
a first electrode and a second electrode, configured to (i) apply one or more voltages that reverse-bias the reverse-biased semiconductor junction and (ii) output the electrical signal.

2. The optical communication system according to claim 1, wherein the first layers comprise at least a silicon layer and a germanium layer.

3. The optical communication system according to claim 1, wherein the stack of layers is compatible for fabrication with a Complementary Metal-Oxide-Semiconductor (CMOS) fabrication process.

4. The optical communication system according to claim 1, wherein at least one of the layers in the stack belongs both to the first layers and to the second layers.

5. The optical communication system according to claim 1, wherein the second layers form a forward-biased semiconductor junction, and wherein the one or more voltages are set to bias both the forward-biased semiconductor junction and the reverse-biased semiconductor junction.

6. The optical communication system according to claim 5, further comprising a third electrode, which is connected between the forward-biased semiconductor junction and the reverse-biased semiconductor junction and is configured to apply an additional voltage for applying a further bias to the forward-biased semiconductor junction and to the reverse-biased semiconductor junction.

7. The optical communication system according to claim 1, wherein the second layers comprise at least one dielectric layer and at least one metal layer that form a capacitor.

8. The optical communication system according to claim 1, wherein the stack of layers comprises:
an N-doped silicon layer;
a P-doped silicon layer disposed on or in the N-doped silicon layer;
an intrinsic (I) germanium layer disposed on the P-doped silicon layer; and
an additional N-doped silicon layer disposed on the germanium layer.

9. The optical communication system according to claim 1, wherein the stack of layers comprises:
a P-doped silicon layer;
an N-doped silicon layer disposed on or in the P-doped silicon layer;
an intrinsic (I) germanium layer disposed on the N-doped silicon layer; and
an additional P-doped silicon layer disposed on the germanium layer.

10. A method of manufacturing an optical communication system, the method comprising:
disposing, on a substrate, a photodetector (PD) for converting an optical signal into an electrical signal, including disposing:
a stack of layers, comprising at least:
first layers including two or more semiconductor layers a reverse-biased semiconductor junction configured to produce the electrical signal in response to the optical signal impinging thereon; and
second layers forming a capacitance component that is connected in series with the reverse-biased semiconductor junction; and
a first electrode and a second electrode, configured to (i) apply one or more voltages that reverse-bias the reverse-biased semiconductor junction and (ii) output the electrical signal; and
disposing, on a substrate, an optical waveguide for receiving and guiding the optical signal to the PD.

11. The method of manufacturing according to claim 10, wherein disposing the first layers comprises disposing at least a silicon layer and a germanium layer.

12. The method of manufacturing according to claim 10, wherein disposing the stack of layers is performed in a Complementary Metal-Oxide-Semiconductor (CMOS) fabrication process.

13. The method of manufacturing according to claim 10, wherein at least one of the layers in the stack belongs both to the first layers and to the second layers.

14. The method of manufacturing according to claim 10, wherein disposing the second layers comprises forming a forward-biased semiconductor junction, the one or more voltages biasing both the forward-biased semiconductor junction and the reverse-biased semiconductor junction.

15. The method of manufacturing according to claim 14, further comprising disposing a third electrode connected between the forward-biased semiconductor junction and the reverse-biased semiconductor junction, for applying an additional voltage that applies a further bias to the forward-biased semiconductor junction and to the reverse-biased semiconductor junction.

16. The method of manufacturing according to claim 10, wherein disposing the second layers comprises disposing at least one dielectric layer and at least one metal layer that form a capacitor.

17. The method of manufacturing according to claim 10, wherein disposing the stack of layers comprises:
disposing an N-doped silicon layer on the substrate;
disposing a P-doped silicon layer on or in the N-doped silicon layer;
disposing an intrinsic (I) germanium layer on the P-doped silicon layer; and
disposing an additional N-doped silicon layer on the germanium layer.

18. The method of manufacturing according to claim 10, wherein disposing the stack of layers comprises:
disposing a P-doped silicon layer on the substrate;
disposing an N-doped silicon layer on or in the P-doped silicon layer;
disposing an intrinsic (I) germanium layer on the N-doped silicon layer; and
disposing an additional P-doped silicon layer on the germanium layer.

19. The method of manufacturing according to claim 10 wherein disposing the stack of layers comprises growing the layers epitaxially on one another.
